(19) United States
(12) Patent Application Publication
(10) Pub. No.: US 2026/0229383 A1
(43) Pub. Date: Aug. 6, 2026

(54) HIGH VOLTAGE RESISTIVE CONDUCTOR CABLE FOR OPERATION UNDER VACUUM CONDITIONS

(71) Applicant: Applied Materials Israel Ltd., Rehovot (IL)

(72) Inventors: Anton Tsyganok, Holon (IL); Yosef Basson, Mazkeret-Batya (IL); Ittamar Levy, Rehovot (IL)

(73) Assignee: Applied Materials Israel Ltd., Rehovot (IL)

(21) Appl. No.: 19/045,447

(22) Filed: Feb. 4, 2025

(51) Int. Cl. H01B 1/18; H01B 3/44; H01B 7/04; H01J 37/28

(52) U.S. Cl. CPC H01B 1/18; H01B 3/445; H01B 7/04; H01J 37/28

(57) ABSTRACT

There is provided a high voltage (HV) resistive conductor cable for operation under vacuum conditions, the cable including a resistive conductor core coated with an insulating material configured to prevent leakage of contaminants when operating under vacuum conditions, wherein said resistive conductor core includes glassy fibers and conductive carbon, wherein the conductive carbon is about 2-25 % (w/w) of the resistive conductor core, such that the resistive conductor core is characterized by having an electric resistance of about 1-500 kΩ/m and by being configured to withstand a temperature of at least about 250° C.

### TECHNICAL FIELD

The present disclosure relates to the field of resistive conductors for operation under vacuum conditions. More specifically, the disclosure relates to a high voltage (HV) resistive conductor cable comprising a resistive conductor core coated with an insulating material.

### BACKGROUND OF THE INVENTION

Electron microscopy tools, particularly scanning electron microscopes, function at high voltages. As advancements in these tools progress, the demand for even higher voltages is increasing, presenting new technological challenges. One common requirement when delivering high voltages to certain components via a high-voltage (HV) cable is the inclusion of a resistor. This resistor plays a crucial role in safeguarding the systems and elements from damage during high-voltage discharge events by minimizing energy dissipation.

However, integrating such a protective resistor can present complications, as it requires additional space within the tool for proper placement. Furthermore, adding a resistor increases the overall weight of the tool and necessitates extra components, such as connectors. Therefore, there is a need in the art for simplifying the design of certain elements which require HV cable including a resistor, within the tool.

### BRIEF SUMMARY OF THE INVENTION

The disclosure is directed, in embodiments thereof, to a high voltage (HV) resistive conductor cable including a resistive conductor core made of a composite material, which cable is suitable for operation under vacuum conditions, and which obviates the need for incorporating resistors. The resistive conductor core is covered by an insulating material, which advantageously prevents leakage of contaminants from the core to the surrounding of the cable.

According to some embodiments, the resistive conductor (composite material) core includes glassy fibers and conductive carbon. Advantageously, the resistive conductor core is configured to withstand high temperatures, such as at least about 250° C., at least about 300° C., or at least about 350° C. In some embodiments, the resistive conductor core is configured to withstand temperature sufficiently high to melt the insulating material.

There is provided, in accordance with some embodiments, a method for producing the resistive conductor cable. In some embodiments, the method includes heating the insulating material (at a temperature of at least about 250° C., about 300° C., or about 350° C.). In some embodiments, the insulating material, heated to above around its melting temperature, is superimposed around the resistive conductor core, to produce the resistive conductor core coated with the insulating material. In some embodiments, the insulating material is superimposed around the resistive conductor core while the insulating material is at a temperature above 220° C., thereby heating the core to at least 200° C.

Advantageously, the resistive conductor core is characterized by high cycle fatigue (HCF). In some embodiments, the resistive conductor cable is characterized by a low bending diameter, such as about 5-20 times, or 5-10 times the diameter size thereof, while experiencing recurring motions of the cable.

In some embodiments, the resistive conductor core is characterized by an electric resistance of about 1-500 kΩ/m.

Further provided, according to some embodiments, is the use of the resistive conductor cable disclosed herein in an electron microscope, such as a scanning electron microscope (SEM). In some embodiments, the resistive conductor cable electrically connects between a high-voltage power supply and an element in the SEM, for example, a wafer-holding assembly.

There is provided, in accordance with some embodiments, a high voltage (HV) resistive conductor cable for operation under vacuum conditions, the cable including a resistive conductor core coated with an insulating material configured to prevent leakage of contaminants when operating under vacuum conditions, wherein said resistive conductor core includes glassy fibers and conductive carbon, wherein the conductive carbon is about 2-25% (w/w) of the resistive conductor core, such that the resistive conductor core is characterized by having an electric resistance of about 1-500 kΩ/m and by being configured to withstand a temperature of at least about 250° C.

According to some embodiments, the resistive conductor core is characterized by a bending diameter of about 5-20 times the diameter size thereof, when the HV resistive conductor cable is in a recurrent motion.

According to some embodiments, the resistive conductor core is characterized by a bending diameter of about 5-10 times the diameter size thereof, when the HV resistive conductor cable is in a recurrent motion.

According to some embodiments, the conductive carbon is selected from a group consisting of graphitic carbon, amorphous carbon, pyrolyzed carbon, doped carbon, carbon aerogel or foam, carbon quantum dots or nanodots, carbon-organic composite, onion-like carbon, mesoporous carbon, and any combination thereof.

According to some embodiments, the graphitic carbon is selected from a group consisting of graphite, graphene, expanded graphite, pyrolytic graphite, graphene oxide (reduced), graphite oxide nanoparticles (reduced), graphene oxide nanoparticles (reduced), graphene quantum dots, graphene nanoparticles, graphene nanoplatelets, graphene oxide nanosheets, graphene-functionalized nanoparticles, carbon nanotube-graphene composites, graphite nanoparticles, graphite nanosheet, graphite nanofibers, graphitic carbon nitride (g-C3N4), few-layer graphene, highly oriented pyrolytic graphite (HOPG), multilayer graphene, carbon nanotubes (CNTs), carbon nanofibers (CNFs), fullerenes (e.g., C60), carbon nanocages, and any combination thereof.

According to some embodiments, the graphitic carbon is selected from a group consisting of graphite, graphene, expanded graphite, pyrolytic graphite, graphene oxide (reduced), graphene oxide nanoparticles (reduced), graphite oxide nanoparticles (reduced), graphene quantum dots, graphene nanoparticles, graphene nanoplatelets, graphene oxide nanosheets, graphene-functionalized nanoparticles, carbon nanotube-graphene composites, graphite nanoparticles, graphite nanosheet, graphite nanofibers, carbon nanotubes (CNTs), and any combination thereof.

According to some embodiments, the glassy fibers are selected from a group consisting of fiberglass, silicon rubber fibers, basalt fibers, boron fibers, borosilicate fibers, any derivative thereof, and any combination thereof.

According to some embodiments, the resistive conductor core includes glassy fibers selected from: fiberglass, basalt fibers, and borosilicate fibers, and graphitic carbon selected from: graphite, graphene, graphite oxide nanoparticles (reduced), graphene nanoparticles, graphene nanoplatelets, graphene oxide nanosheets, graphene-functionalized nanoparticles, graphite nanoparticles, graphite nanosheet, graphite nanofibers, and any combination thereof.

According to some embodiments, the glassy fibers are coated with the conductive carbon.

According to some embodiments, the insulating material includes polytetrafluoroethylene (PTFE), polyimide, silicon rubber, polyethylene (PE), polyvinyl chloride (PVC), fluorinated ethylene propylene (FEP), any derivative thereof, any co-polymer thereof, or any combination thereof.

According to some embodiments, the insulating material is PTFE.

According to some embodiments, the vacuum conditions are characterized by a pressure range of between 10⁻⁵ to 1·10⁻¹² Torr.

According to some embodiments, the cable is configured to operate at a high voltage (HV) of between about 10 kV to 500 kV.

According to some embodiments, the high voltage (HV) is in a range of between about 10 kV to 300 kV.

According to some embodiments, the resistive conductor core is stable at a temperature of at least about 300° C.

According to some embodiments, the resistive conductor core is characterized by an electric resistance of about 10-100 kΩ/m.

There is provided, in accordance with some embodiments, a scanning electron microscope (SEM) including a high voltage (HV) resistive conductor cable for operation under vacuum conditions, the cable comprising a resistive conductor core coated with an insulating material configured to prevent leakage of contaminants therethrough when operating under vacuum conditions, wherein said resistive conductor core includes glassy fibers and conductive carbon, wherein the conductive carbon is about 2-25% (w/w) of the resistive conductor core, such that the resistive conductor core is characterized by having an electric resistance of about 1-500 kΩ/m and by being configured to withstand a temperature of at least about 250° C.

According to some embodiments, the high voltage (HV) resistive conductor cable is located in a vacuum chamber of the SEM.

There is provided, in accordance with some embodiments, a method of producing a high voltage (HV) resistive conductor cable for operation under vacuum conditions, the method including:
providing a resistive conductor core including glassy fibers and conductive carbon, wherein the conductive carbon is about 2-25% (w/w) of the resistive conductor core and wherein the resistive conductive core is characterized by having a resistance of about 1-500 kΩ/m and by being configured to withstand a temperature of at least about 250° C.;
superimposing an insulating material around the resistive conductor core, wherein the insulating material is configured to prevent leakage of contaminants therethrough when operating under vacuum conditions; and
heating the insulating material at a temperature of at least about 250° C., to produce the high voltage (HV) resistive conductor cable suitable for use under vacuum conditions.

According to some embodiments, the heating temperature is at least about 300° C.

Certain embodiments of the present disclosure may include some, all, or none of the above advantages. One or more technical advantages may be readily apparent to those skilled in the art from the figures, descriptions and claims included herein. Moreover, while specific advantages have been enumerated above, various embodiments may include all, some or none of the enumerated advantages.

In addition to the exemplary aspects and embodiments described above, further aspects and embodiments will become apparent by reference to the figures and by study of the following detailed descriptions.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not to scale.

In the figures:

FIG. 1 shows a flow chart of steps of a method for producing a resistive conductor cable, in accordance with some embodiments;

FIG. 2 shows a photograph of an insulated resistive conductor core, in accordance with some embodiments;

FIG. 3 shows a line graph of forced discharge current measurements performed on a 5 m, insulated, resistive conductor core disclosed herein. The resistive conductor core has a resistance of 173kΩ, in accordance with some embodiments;

FIG. 4 shows a line graph of forced discharge current measurements performed on the herein disclosed resistive conductor core, in accordance with some embodiments;

FIG. 5 shows a line graph of forced discharge current measurements performed on a 6 m coax cable (i.e., coaxial cable) connected to a 1.5 kΩ resistor, in accordance with some embodiments;

FIG. 6 shows a simulated line graph of a discharge current behavior vs. time when applying a 10 kV voltage to a model of a standard coax connected to a resistor, in accordance with some embodiments; and

FIG. 7 shows a line graph of experimental results of discharge current behavior vs. time when applying a voltage of 10 kV to the herein disclosed resistive conductor core, in accordance with some embodiments.

### DETAILED DESCRIPTION OF THE INVENTION

Protecting elements in electron microscope systems during high-voltage discharge events often requires resistors connected to HV cables, to reduce energy dissipation. However, integrating resistors requires additional space and increases the overall weight and volume of the tools, necessitating extra components like connectors or resistor box. Advantageously, the hereindisclosed resistive conductor cable eliminates the need for incorporating resistors. The herein disclosed resistive conductor cable thus advantageously simplifies the design of certain elements in the tools, such as wafer-holding assemblies.

HV cables with internal resistance, such as the herein disclosed resistive conductor cables, eliminate the need for resistors. However, the sensitive vacuum working environment, which is required in electron microscopes, adds a challenge to the design of HV cables with internal resistance. This is because, in addition to the required electric and mechanical properties of the HV resistive conductor cables, the cables must not release any contaminants into the sensitive vacuum working environment. Advantageously, the hereindisclosed resistive conductor cable is non-contaminating and is thus suitable for operation under vacuum conditions. The hereindisclosed HV resistive conductor cable includes a resistive conductor core made of composite material including glassy fibers and conductive carbon. The advantageous core, thus, contains both conductive and non-conductive materials. Further, the resistive conductor core is coated with an insulating material, such as Teflon®. This coating, advantageously, prevents leakage of contaminants from the core to the vacuum environment and thus protects the sensitive environment of the microscope.

Importantly, the herein disclosed resistive conductor core is also configured to withstand the high temperature that is required to deposit the insulating material thereon, during a production process of the herein disclosed HV resistive conductor cable.

There is provided herein, in accordance with some embodiments, a high voltage (HV) resistive conductor cable for operation under vacuum conditions, the cable including a resistive conductor core with an insulating material configured to prevent leakage of contaminants when operating under vacuum conditions, wherein said resistive conductor core includes glassy fibers and conductive carbon, wherein the conductive carbon is about 2-25% (w/w) of the resistive conductor core, such that the resistive conductor core is characterized by a resistance of about 1-500 kΩ/m and by being configured to withstand a temperature of at least about 250° C.

Electron microscopy imaging is a method that is sensitive to a residual amount of contaminants that might be present in the vacuum chamber of the tool, such as, but not limited to, water, silicon-, metal-, or carbon-based contaminants. Advantageously, according to some embodiments, the coating insulating material is an insulating layer that prevents leakage of potential contaminants from the resistive conductor core into an operating (high) vacuum chamber. In some embodiments, an operating vacuum chamber is protected from contaminants originating from the resistive conductor core disclosed herein. In some embodiments, the insulating material reduces or eliminates leakage of contaminants that may originate from the resistive conductor core. In some embodiments, fluorinated polymers, for example, polytetrafluoroethylene (i.e., Teflon®) or fluorinated ethylene propylene (FEP), may prevent or reduce the leakage/passage of contaminants from the resistive conductor core to an operating high vacuum chamber. According to some further embodiments, the insulating material may prevent/reduce cross-contamination from/to the vacuum environment to/from the resistive conductor cable/core.

According to some embodiments, the insulating material coats the resistive conductor core by physically associating with the core. According to some other embodiments, the insulating material coats the resistive conductor core by at least partially physically associating with the core. According to some other embodiments, the insulating material coats the resistive conductor core by functionally associating with the core. According to some other embodiments, the insulating material coats the resistive conductor core by approximately associating with the core.

According to some embodiments, the glassy fibers are coated with the conductive carbon by a physical association. According to some embodiments, the glassy fibers are coated with the conductive carbon by at least partial physical association. According to some embodiments, the glassy fibers are coated with the conductive carbon by at least partial functional association with the glassy fibers. According to some embodiments, the glassy fibers are impregnated with the conductive carbon. According to some embodiments, the glassy fibers are mixed with the conductive carbon.

As used herein, in accordance with some embodiments, the term “functional association” or “functionally associated” refers to any type of association between two or more materials, such as, but not limited to, insulating material, glassy fibers, and/or conductive carbon, that result in a functional effect. In some embodiments, the functional association may be any connection (direct/indirect) between any of said materials that render them with a new functionality. In some embodiments, the functional association may include an additional direct/indirect association with an additional material (physically/partially physically / functionally). In some exemplifying embodiments, the conductive carbon renders the composite material conductive. In some exemplifying embodiments, the glassy fibers render the composite material resistive. In some other exemplifying embodiments, the insulating material prevents/minimizes leakage from the resistive conductor cable.

According to some embodiments, the resistive conductor core is characterized by a relatively low bending diameter.

As used herein, in accordance with some embodiments, the term “bending diameter” refers to the minimum diameter around which a material, such as, but not limited to, wire, cable, pipe, or flexible polymer, can be bent without experiencing permanent deformation, damage, or a reduction in its performance. In some embodiments, the material maintains its structural integrity and functionality under bending.

In some embodiments, a low bending diameter of the resistive conductor core or the resistive conductor cable allows a non-harming (recurrent) motion thereof.

According to some embodiments, the resistive conductor cable is characterized by a bending diameter which does not harm the resistive conductor core or cable. According to some embodiments, the resistive conductor cable is characterized by a bending diameter of about 3-20 times the diameter size thereof, when the HV resistive conductor cable is under a recurrent motion. According to some embodiments, the resistive conductor cable is characterized by a bending diameter of about 5-20 times the diameter size thereof, when the HV resistive conductor cable is under a recurrent motion. For example, the resistive conductor cable is characterized by a bending diameter of about 5-20 times the diameter size thereof, about 5-19 times the diameter size thereof, about 5-18 times the diameter size thereof, about 5-16 times the diameter size thereof, about 5 -15 times the diameter size thereof, about 5-13 times the diameter size thereof, about 5-12 times the diameter size thereof, about 5-10 times the diameter size thereof, when the HV resistive conductor cable is under a recurrent motion. Each possibility is a separate embodiment.

According to some embodiments, the resistive conductor core is configured to withstand recurring motion without breaking. In some embodiments, the resistive conductor core is configured to withstand at least 1,000 motion cycles, for example, 1,000-10,000 motion cycles, 10,000-100,000 motion cycles, or 100,000-1,000,000 motion cycles, without breaking. In some embodiments, the resistive conductor core is configured to withstand at least 1 million motion cycles, for example, at least 10 to 50 million motion cycles, at least 50 to 100 million motion cycles, at least 100 million to 1 billion motion cycles, at least 10 billion motion cycles, at least 100 billion motion cycles, at least 1 trillion motion cycles, at least 10 trillion motion cycles, at least 100 trillion motion cycles, at least 1 quadrillion motion cycles, at least 10 quadrillion motion cycles, at least 100 quadrillion motion cycles, at least 1 quintillion motion cycles, at least 1 sextillion motion cycles, at least 1 septillion motion cycles, at least 1 octillion motion cycles, at least 1 nonillion motion cycles, or at least 1 decillion motion cycles, without breaking. Each possibility is a separate embodiment.

According to some embodiments, the resistive conductor cable is configured to withstand recurring motion without breaking. In some embodiments, the resistive conductor cable is configured to withstand at least 1,000 motion cycles, for example, 1,000-10,000 motion cycles, 10,000-100,000 motion cycles, or 100,000-1,000,000 motion cycles, without breaking. In some embodiments, the resistive conductor cable is configured to withstand at least 1 million motion cycles, for example, at least 10 to 50 million motion cycles, at least 50 to 100 million motion cycles, at least 100 million to 1 billion motion cycles, at least 10 billion motion cycles, at least 100 billion motion cycles, at least 1 trillion motion cycles, at least 10 trillion motion cycles, at least 100 trillion motion cycles, at least 1 quadrillion motion cycles, at least 10 quadrillion motion cycles, at least 100 quadrillion motion cycles, at least 1 quintillion motion cycles, at least 1 sextillion motion cycles, at least 1 septillion motion cycles, at least 1 octillion motion cycles, at least 1 nonillion motion cycles, or at least 1 decillion motion cycles, without breaking. Each possibility is a separate embodiment.

In some other embodiments, when the motion is a sporadic event, the bending diameter value disclosed herein may be further reduced. In some embodiments, when the motion is sporadic, the bending diameter disclosed herein may be further reduced by at least about 25%, for example, by at least about 30%, by at least about 35%, by at least about 40%, by at least about 45%, or by at least about 50%, as compared with the bending diameter obtained under the recurring motion as mentioned hereinbefore. Each possibility is a separate embodiment.

According to some embodiments, the resistive conductor core is characterized by high cycle fatigue (HCF).

As used herein, in accordance with some embodiments, the term “high cycle fatigue” or “HCF” refers to a failure of the resistive conductor core under cyclic (recurring) mechanical loading (e.g., bending) conditions where the number of mechanical load cycles to failure is high.

In some embodiments, the HCF exceeds about 104 to 107 cycles, for example, about 10.106 to 50.106 motion cycles, about 50-106 to 100.106 motion cycles, or about 100-106 to 1.107 motion cycles. Each possibility is a separate embodiment.

According to some embodiments, the conductive carbon is about 2-25% (w/w) of the resistive conductor core, for example, about 3-24% (w/w), about 5-22% (w/w), about 5-20% (w/w), about 5-25% (w/w), about 5-18% (w/w), about 5-15% (w/w), about 5-10% (w/w), about 10-24% (w/w), about 10-15% (w/w), or about 15-22% (w/w). Each possibility is a separate embodiment.

According to some embodiments, the conductive carbon may include, but is not limited to, graphitic carbon, amorphous carbon, pyrolyzed carbon, doped carbon, carbon aerogel or foam, carbon quantum dots or nanodots, carbon-organic composite, onion-like carbon, mesoporous carbon, or any combination thereof. Each possibility is a separate embodiment.

According to some embodiments, the graphitic carbon may include, but not limited to, graphite, graphene, expanded graphite, pyrolytic graphite, graphene oxide (reduced), graphite oxide nanoparticles (reduced), graphene oxide nanoparticles (reduced), graphene quantum dots, graphene nanoparticles, graphene nanoplatelets, graphene oxide nanosheets, graphene-functionalized nanoparticles, carbon nanotube-graphene composites, graphite nanoparticles, graphite nanosheet, graphite nanofibers, graphitic carbon nitride (g-C3N4), few-layer graphene, highly oriented pyrolytic graphite (HOPG), multilayer graphene, carbon nanotubes (CNTs), carbon nanofibers (CNFs), fullerenes (e.g., C60), carbon nanocages, or any combination thereof. Each possibility is a separate embodiment.

In some embodiments, the graphitic carbon may include, but not limited to, graphite, graphene, expanded graphite, pyrolytic graphite, graphene oxide (reduced), graphene oxide nanoparticles (reduced), graphite oxide nanoparticles (reduced), graphene quantum dots, graphene nanoparticles, graphene nanoplatelets, graphene oxide nanosheets, graphene-functionalized nanoparticles, carbon nanotube-graphene composites, graphite nanoparticles, graphite nanosheet, graphite nanofibers, carbon nanotubes (CNTs), or any combination thereof. Each possibility is a separate embodiment.

In some embodiments, the graphitic carbon includes graphene oxide nanoparticles (reduced), graphite oxide nanoparticles (reduced), graphene quantum dots, graphene nanoparticles, graphene nanoplatelets, graphene oxide nanosheets, graphene-functionalized nanoparticles, graphite nanoparticles, graphite nanosheet, graphite nanofibers, or any combination thereof. Each possibility is a separate embodiment. In some embodiments, the graphitic carbon includes, or is, graphite nanoparticles.

According to some embodiments, the conductive carbon may include amorphous carbon material selected from, but not limited to, carbon black, activated carbon, amorphous carbon, acetylene black, channel black, furnace black, lamp black, thermal black, charcoal, glassy carbon, diamond-like carbon (DLC) coatings, or any combination thereof. Each possibility is a separate embodiment.

According to some embodiments, the conductive carbon may include pyrolyzed carbon material selected from, but not limited to, pyrolytic carbon, carbonized polymer fibers, carbonized cellulose fibers, carbonized aerogels, carbonized lignin, carbonized polyacrylonitrile (PAN), hard carbon (derived from sugars or starches), carbonized wood, biochar, or any combination thereof. Each possibility is a separate embodiment.

According to some embodiments, the conductive carbon may include a doped carbon material selected from, but not limited to, nitrogen-doped graphene, boron-doped carbon nanotubes, sulfur-doped carbon, phosphorus-doped carbon, nitrogen-doped carbon nanofibers, boron-doped diamond-like carbon, oxygen-doped graphene, boron-doped graphene, nitrogen-doped carbon black, sulfur-doped activated carbon, or any combination thereof. Each possibility is a separate embodiment. As used herein, in accordance with some embodiments, the term “doped” refers to a material in which a ‘doping element’ (defined thereafter) has been introduced to alter the properties thereof.

In some embodiments, the conductive carbon may include a doped carbon material selected from, but not limited to, nitrogen-doped graphene, oxygen-doped graphene, boron-doped graphene, nitrogen-doped graphite, oxygen-doped graphite, boron-doped graphite, or any combination thereof. Each possibility is a separate embodiment. In some embodiments, the conductive carbon may include a doped carbon material selected from, but not limited to, nitrogen-doped graphite nanoparticles, oxygen-doped graphite nanoparticles, boron-doped graphite nanoparticles, or any combination thereof. Each possibility is a separate embodiment.

According to some embodiments, the conductive carbon may include a carbon aerogel or foam selected from, but not limited to, carbon aerogel, carbon foam, graphene aerogel, carbon xerogel, metal-doped carbon aerogel, resorcinol-formaldehyde carbon aerogel, polyaniline-based carbon aerogel, carbon-polymer composite foam, graphene foam, carbon nanotube-based foam, or any combination thereof. Each possibility is a separate embodiment.

According to some embodiments, the conductive carbon may include carbon quantum dots or nanodots selected from, but not limited to, carbon nanodots, nitrogen-doped carbon dots, boron-doped carbon quantum dots, sulfur-doped carbon dots, phosphorus-doped carbon nanodots, carbon dots with surface functionalization, blue-emitting carbon quantum dots, green-emitting carbon dots, fluorescent carbon quantum dots, or any combination thereof. Each possibility is a separate embodiment. As used herein, in accordance with some embodiments, the terms “carbon quantum dots” or “nanodots” refer to nanometer-scale particles of carbon (typically smaller than 10 nm) that exhibit unique optical, electronic, and chemical properties.

According to some embodiments, the conductive carbon may include a carbon-based composite selected from, but not limited to, carbon-based polymer composite, carbon black-reinforced rubber, carbon fiber-reinforced polymer, conductive carbon ink, graphene-polymer composite, CNT-polymer composite, carbon-coated metal particles, graphite-filled epoxy, carbon-coated silica, or any combination thereof. Each possibility is a separate embodiment.

According to some embodiments, the conductive carbon may include an onion-like carbon (OLC) selected from, but not limited to, pure onion-like carbon (OLC), OLC from detonation nanodiamonds, doped onion-like carbon (e.g., nitrogen-doped OLC), metal-supported OLC, boron-doped onion-like carbon, high-temperature annealed OLC, surface-functionalized OLC, oxidized OLC, reduced OLC, graphitized onion-like carbon, or any combination thereof. Each possibility is a separate embodiment. As used herein, in accordance with some embodiments, the term “onion-like carbon” or “OLC” refers to a unique form of carbon nanostructure composed of concentric, spherical layers of graphitic carbon, resembling the layers of an onion. In some embodiments, these structures are typically a few nanometers in size and have remarkable physical and chemical properties.

According to some embodiments, the conductive carbon may include a mesoporous carbon material selected from, but not limited to, mesoporous carbon, ordered mesoporous carbon (OMC), mesoporous carbon derived from silica templates, mesoporous carbon spheres, CMK-3 (a type of ordered mesoporous carbon), porous carbon derived from resorcinol-formaldehyde, hierarchically porous carbon, mesoporous carbon nanofibers, nitrogen-doped mesoporous carbon, phosphorus-doped mesoporous carbon, or any combination thereof. Each possibility is a separate embodiment.

According to some embodiments, the resistive conductor core may include a doping element. As used herein, in accordance with some embodiments, the term “doping element” refers to an impurity (or a residual amount of a chemical element) intentionally introduced into a material, to modify its electrical, optical, or structural properties. In some embodiments, the doping element may increase the conductivity of the core. In some embodiments, the doping element may decrease the conductivity of the core.

According to some embodiments, the doping element may be selected from: Phosphorus (P), Arsenic (As), Antimony (Sb), boron (B), aluminum (Al), Gallium (Ga), Nitrogen (N), Cobalt (Co), Oxygen (O), chlorine (CI), sodium (Na), lithium (Li), potassium (K), magnesium (Mg), zinc (Zn), silicon (Si), Cadmium (Cd), fluorine (F), Antimony (Sb), sulfur(S), or any combination thereof. Each possibility is a separate embodiment.

According to some embodiments, the doping element may be included in the conductive carbon and/or in the glassy fibers. According to some embodiments, the doping element may be impregnated in the conductive carbon and/or in the glassy fibers. According to some embodiments, the doping element may be mixed with the conductive carbon and/or with the glassy fibers. In some embodiments, the doping element may superimpose the resistive conductor core. In some embodiments, the doping element may intercalate between the conductive carbon and the glassy fibers.

According to some embodiments, the resistive conductor core including the glassy fibers and the conductive carbon, is a composite material including, but not limited to, at least the conductive carbon and the glassy fibers. According to some embodiments, the resistive conductive core including the glassy fibers and the conductive carbon is a composite material.

According to some embodiments, a yarn of glassy fibers is coated with the conductive carbon and is a composite material including, but not limited to, at least the conductive carbon and the glassy fibers. In some embodiments, the composite material herein includes a conductive material (e.g., the conductive carbon) and a non/less-conductive material (e.g., the glassy fibers (yarn)). In some embodiments, the non-conductive material contributes to the resistance of the resistive conductor core. In some embodiments, the conductive material contributes to the conductivity of the resistive conductor core.

According to some embodiments, the glassy fibers are impregnated with the conductive carbon. In some embodiments, the conductive carbon is impregnating the glassy fibers between the fibers and/or around the glassy fibers.

According to some embodiments, the glassy fibers may include, but not limited to, Silica (SiO₂), alumina (Al₂O₃), calcium oxide (CaO), boron oxide (B₂O₃), magnesium oxide (MgO), or any combination thereof. According to some embodiments, the glassy fibers may include a binding material. In some embodiments, the binding material may include a polymer. In some embodiments, the polymer binding material may include, but not limited to, polyester resin, epoxy resin, vinyl ester resin, or any combination thereof. In some embodiments, the glassy fibers may include a filler.

According to some embodiments, the glassy fibers are selected from, but not limited to, fiberglass, silicon rubber fibers, basalt fibers, alumina fibers, boron fibers, zirconia fibers, titania fibers, silicon carbide fibers, borosilicate fibers, or any combination thereof. Each possibility is a separate embodiment.

According to some embodiments, the glassy fibers are selected from, but are not limited to, fiberglass, silicon rubber fibers, basalt fibers, boron fibers, borosilicate fibers, or any combination thereof. Each possibility is a separate embodiment.

According to some embodiments, the resistive conductor core includes glassy fibers which are selected from: fiberglass, basalt fibers, and borosilicate fibers, and includes graphitic carbon which is selected from: graphite, graphene, graphite oxide nanoparticles (reduced), graphene nanoparticles, graphene nanoplatelets, graphene oxide nanosheets, graphene-functionalized nanoparticles, graphite nanoparticles, graphite nanosheet, graphite nanofibers, and any combination thereof.

In some embodiments, the glassy fibers are coated with the conductive carbon. In some embodiments. The glassy fibers are mixed with the conductive carbon.

In some embodiments, the resistive conductor core includes glassy fibers in an amount of 75-98% (w/w) and conductive carbon in an amount of 2-25% (w/w) of the core. In some embodiments, the resistive conductor core includes glassy fibers in an amount of 80-98% (w/w) and conductive carbon in an amount of 2-20% (w/w) of the core. In some embodiments, the resistive conductor core includes glassy fibers in an amount of 90-98% (w/w) and conductive carbon in an amount of 2-10% (w/w) of the core. In some embodiments, the resistive conductor core includes glassy fibers in an amount of 75-85% (w/w) and conductive carbon in an amount of 15-25% (w/w) of the core.

In some embodiments, the resistive conductor core includes glassy fibers selected from: fiberglass, basalt fibers, and borosilicate fibers, in an amount of 75-98% (w/w) of the core, and conductive carbon selected from: graphite, graphene, graphite oxide nanoparticles (reduced), graphene nanoparticles, graphene nanoplatelets, graphene oxide nanosheets, graphene-functionalized nanoparticles, graphite nanoparticles, graphite nanosheet, graphite nanofibers, in an amount of 2-25% (w/w) of the core. In some embodiments, the resistive conductor core includes fiberglass, basalt fibers, or borosilicate fibers, in an amount of 75-98% (w/w) of the core, and graphite, graphene, graphene nanoparticles, graphene-functionalized nanoparticles, or graphite nanoparticles, in an amount of 2-25% (w/w) of the core. In some embodiments, the resistive conductor core includes basalt fibers in an amount of 75-98% (w/w) of the core, and graphite, in an amount of 2-25% (w/w) of the core. In some embodiments, the resistive conductor core includes fiberglass in an amount of 75-98% (w/w) of the core, and graphene-functionalized nanoparticles in an amount of 2-25% (w/w) of the core. In some embodiments, the resistive conductor core includes borosilicate fibers in an amount of 75-98% (w/w) of the core, and graphite nanoparticles in an amount of 2-25% (w/w) of the core. In some embodiments, the resistive conductor core includes fiberglass in an amount of 75-98% (w/w) of the core, and graphite nanoparticles in an amount of 2-25% (w/w) of the core. In some embodiments, the resistive conductor core includes borosilicate fibers in an amount of 75-98% (w/w) of the core, and graphene nanoparticles in an amount of 2-25% (w/w) of the core.

In some embodiments, the resistive conductor core includes glassy fibers selected from: fiberglass, basalt fibers, and borosilicate fibers, in an amount of 75-98% (w/w) of the core, and conductive carbon selected from: graphitic carbon, amorphous carbon, pyrolyzed carbon, doped carbon, carbon aerogel or foam, carbon quantum dots or nanodots, carbon-organic composite, onion-like carbon, mesoporous carbon, in an amount of 2-25% (w/w) of the core. In some embodiments, the resistive conductor core includes fiberglass in an amount of 75-98% (w/w) of the core, and graphitic carbon, in an amount of 2-25% (w/w) of the core. In some embodiments, the resistive conductor core includes borosilicate fibers, in an amount of 75-98% (w/w) of the core, and carbon quantum dots or nanodots, in an amount of 2-25% (w/w) of the core. In some embodiments, the resistive conductor core includes basalt fibers, in an amount of 75-98% (w/w) of the core, and carbon-organic composite, in an amount of 2-25% (w/w) of the core. In some embodiments, the resistive conductor core includes basalt fibers, in an amount of 75-98% (w/w) of the core, and pyrolyzed carbon, in an amount of 2-25% (w/w) of the core.

According to some embodiments, when the glassy fibers are fiberglass, the fiberglass is selected from E-glass, S-glass, or D-glass. Each possibility is a separate embodiment.

According to some embodiments, the glassy fibers are characterized by Size Percentage Loss (SPL) of about 0.7-1.3%. In some embodiments, the term “SPL” or “Size Percentage Loss”, refers to a measure used to evaluate the proportion of surface sizing material that is lost from the fibers during processing. In some embodiments, the SPL of the glassy fibers is about 0.75-1.25%, for example, about 0.75-1.20%, about 0.8-1.2%, about 0.80-1.15%, about 0.85-1.15%, or about 0.9-1.1%. Each possibility is a separate embodiment.

According to some embodiments, the glassy fibers may include additives, such as, but not limited to, alumina, boron, or calcium.

According to some embodiments, the glassy fibers are a yarn of glassy fibers. As used herein, in accordance with some embodiments, the term “yarn” refers to a bundle of continuous filaments, such as glass filaments, that are twisted or grouped together to form a flexible and strong thread-like structure.

In some embodiments, the glassy fibers may be used as non-conductive material in the resistive conductive composite.

In some embodiments, the glassy fibers and/or the conductive carbon may be used for thermal stability in production processes involving high temperatures (e.g. extrusion).

In some embodiments, the glassy fibers and/or the conductive carbon may be used for mechanical strength and/or mechanical flexibility, in recurring cable motion.

According to some embodiments, the insulating material includes polytetrafluoroethylene (i.e., PTFE or Teflon®), polyimide (e.g. poly (4,4′-oxydiphenylene-pyromellitimide or Kapton®), silicon rubber, polyethylene (PE), polyvinyl chloride (PVC), fluorinated ethylene propylene (FEP), any derivative thereof, any co-polymer thereof, or any combination thereof. Each possibility is a separate embodiment.

In some embodiments, the insulating material may include fluorinated ethylene propylene (FEP), ETFE (Ethylene Tetrafluoroethylene), or Teflon-S (Solvent-Based Coatings). Each possibility is a separate embodiment. The Teflon-S includes PTFE with binders for adhesion to surfaces.

In some embodiments, the insulating material includes Kapton® or silicon.

According to some embodiments, the insulating material includes, or is, polytetrafluoroethylene (i.e., PTFE or Teflon®).

According to some embodiments, the insulating material includes, or is, fluorinated ethylene propylene (FEP).

In some embodiments, the insulating material is used to electrically isolate the resistive conductor core, ensuring safety and efficiency in an electrical system.

In some embodiments, the insulating material is used to physically block the core, thus preventing contaminants originating from the core from leaking out. In some embodiments, the insulating material prevents contaminants originating from the core from reaching the sensitive vacuum environment.

According to some embodiments, the insulating material is in a form of a thin layer. In some embodiments, the insulating material may coat the resistive conductor core with a layer of between about 0.1 μm to about 100 μm, for example, about 0.1-1 μm, about 1-10 μm, or about 1-100 μm. Each possibility is a separate embodiment. In some embodiments, the insulating material may coat the resistive conductor core with a layer of between about 0.1 mm to about 10 mm, for example, about 0.1-1 mm, or about 1-10 μm. Each possibility is a separate embodiment.

According to some embodiments, the vacuum conditions are characterized by a pressure range of between 1·10⁻⁵ to 1·10⁻¹² Torr, for example, between 1·10⁻⁶ to 1·10⁻¹² Torr, between 1·10⁻⁶ to 1·10⁻¹¹ Torr, between 1·10⁻⁶ to 1·10⁻⁸ Torr, between 1·10⁻⁶ to 1·10⁻¹² Torr, between 1·10⁻⁶ to 1·10⁻⁹ Torr, between 1·10⁻⁶to 1·10⁻⁸ Torr, between 1·10⁻⁷ to 1·10⁻⁹ Torr, between 1·19⁻⁶ to 1·10⁻⁷ Torr, between 1·10⁻⁵ to 1·10⁻¹¹ Torr, between 1·10⁻⁵ to 1·10⁻¹⁰ Torr, between 1·10⁻¹¹ to 1· ⁻¹² Torr, or between 1·10⁻¹⁰ to 1·10⁻¹² . Each possibility is a separate embodiment. According to some embodiments, the vacuum conditions are characterized by a pressure range of between 1·10⁻⁴ to 1·10⁻¹³ Torr.

According to some embodiments, the vacuum conditions in which the resistive conductor cable is operated are high vacuum conditions. According to some embodiments, the vacuum conditions in which the resistive conductor cable is operated are ultra-high vacuum conditions. According to some embodiments, the vacuum conditions are applied in a vacuum chamber. As used herein, in accordance with some embodiments, the term “high vacuum” refers to a vacuum environment where the pressure is significantly lower than atmospheric pressure, typically ranging from 10⁻³ to 10⁻⁷ torr (or 1.33×10⁻⁴ to 1.33×10⁻⁵ Pa). As used herein, in accordance with some embodiments, term “ultra-high vacuum” refers to a vacuum environment with pressures below 10⁻⁷ torr (or 1.33×10⁻⁵ Pa), typically ranging from 10⁻⁷ to 10⁻¹² torr.

According to some embodiments, the resistive conductor cable is suitable for vacuum. In some embodiments, the resistive conductor cable suitable for vacuum is configured to release a minimum/residual amount of contaminants or no contaminants at all. In some embodiments, the resistive conductive cable is characterized by a low outgassing. In some embodiments, the cable releases minimal or no amount of volatile compounds, to prevent contamination of the vacuum chamber in which it is operated. In some embodiments, the insulating material of the resistive conductor cable facilitates minimizing or eliminating the outgassing/contamination in the vacuum chamber. In some embodiments, the insulating material of the resistive conductor cable facilitates minimizing the contaminants amount to less than 10 ppm, for example, less than 1 ppm, less than 100 ppb, less than 10 ppb, or less than 1 ppb. Each possibility is a separate embodiment. In some embodiments, the total mass loss towards the vacuum chamber is less than 0.5%, for example, less than 0.3%, less than 0.2%, less than 0.1%, or less than 0.05%. Each possibility is a separate embodiment.

According to some embodiments, the insulating material of the resistive conductor cable facilitates minimizing the hydrocarbon contaminants in the vacuum chamber to less than 100 ppb, for example, to less than 10 ppb, to less than 5 ppb, to less than 1 ppb. Each possibility is a separate embodiment. According to some embodiments, the insulating material of the resistive conductor cable facilitates minimizing the water vapor contamination in the vacuum chamber to less than 10−5 ppm, for example, to less than 5−1 ppm, to less than 1 ppm, to less than 100 ppb, or to less than 10 ppb. Each possibility is a separate embodiment. Each possibility is a separate embodiment.

According to some embodiments, the resistive conductor cable suitable for vacuum is configured to minimize/prevent deformation or degradation of the cable under vacuum. According to some embodiments, the resistive conductor cable suitable for vacuum is configured to resist deformation or degradation.

In some embodiments, owing to its mechanical properties, the resistive conductor cable is configured to minimize/prevent deformation or degradation. In some embodiments, due to its low brittleness, the resistive conductor core is configured to minimize/prevent degradation of the core under (recurring) motion. In some embodiments, owing to its low stiffness, the resistive conductor core is configured to minimize/prevent breakout or degradation of the core under recurrent motion. In some embodiments, owing to its high flexibility, the resistive conductor core resists deformation or degradation under recurrent motion.

In some embodiments, the insulating material resists deformation or degradation owing to its high flexibility. In some embodiments, the insulating material prevents/minimizes degradation/spreading of the resistive conductor core composite material into the vacuum chamber. Minimal or no residuals of the resistive conductor core materials penetrate the insulating material toward the vacuum chamber. In some embodiments, the insulating material prevents the spreading of the resistive conductor cable materials, in general, and the resistive conductor core materials specifically owing to the inert chemical properties of the insulating material. In some embodiments, the insulating material prevents/minimizes the transfer/adherence of contaminants originating from the vacuum chamber and/or examined samples. In some embodiments, the insulating material of the cable prevents/minimizes cross-contamination from/to the resistive conductor core/vacuum chamber.

According to some embodiments, the resistive conductor cable is configured to operate at a high voltage (HV) of about 10 kV to 500 kV, for example, about 10 kV to 400 kV, about 20 kV to 350 kV, about 30 kV to 350 kV, about 40 kV to 300 kV, about 45 kV to 300 kV, about 50 kV to 300 kV, about 50 kV to 250 kV, about 55 kV to 250 kV, about 55 kV to 200 kV, about 60 kV to 190 kV, about 70 kV to 180 kV, about 70 kV to 170 kV, about 50 kV to 160 kV, about 40 kV to 150 kV, about 40 kV to 140 kV, about 30 kV to 140 kV, about 30 kV to 130 kV, about 30 kV to 120 kV, about 30 kV to 110 kV, about 40 kV to 110 kV, about 45 kV to 100 kV, about 50 kV to 120 kV, about 50 kV to 100 kV, about 20 kV to 120 kV, about 100 kV to 450 kV, about 80 kV to 400 kV, about 50 kV to 200 kV, about 20 kV to 100 kV, or about 20 kV to 70 kV. Each possibility is a separate embodiment.

According to some embodiments, the resistive conductor cable is configured to operate at a high voltage (HV) of about 10 kV to 300 kV, for example, about 20 kV to 270 kV, about 20 kV to 250 kV, about 20 kV to 230 kV, about 20 kV to 220 kV, about 20 kV to 200 kV, about 20 kV to 190 kV, about 30 kV to 190 kV, about 35 kV to 190 kV, about 35 kV to 180 kV, about 40 kV to 180 kV, about 50 kV to 170 kV, about 50 kV to 160 kV, about 50 kV to 150 kV, about 55 kV to 145 kV, about 60 kV to 135 kV, or about 60 kV to 130 kV. Each possibility is a separate embodiment.

According to some embodiments, the resistive conductor cable is configured to operate at a high voltage (HV) of about 10 kV to 50 kV, for example, about 15 kV to 40 kV, about 20 kV to 30 kV, or about 40 kV to 50 kV. Each possibility is a separate embodiment.

According to some embodiments, the resistive conductor core is stable at a high temperature. In some embodiments, the core may withstand the high temperature to which it is exposed. In some embodiments, the resistance to the high temperature is during a production process of the resistive conductor cable. In some embodiments, the resistive conductor core is configured to resist the high temperature when heated continuously and/or intermittently. In some embodiments, the resistive conductor core is configured to withstand the high temperature for about 1-800 min, continuously or as a sum of intermittent heating periods, for example, for about 1-700 min, for about 1-10 min, for about 1-5 min, for about 5-30 min, for about 5-60 min, for about 30-240 min, or for about 60-600 min. Each possibility is a separate embodiment.

According to some embodiments, the resistive conductor core is stable at a temperature of at least about 250° C., for example, at least about 260° C., at least about 270° C., at least about 280° C., at least about 290 ° C., at least about 300° C., at least about 310° C., at least about 320° C., at least about 330° C., at least about 340° C., at least about 350° C., at least about 360° C., or at least about 370° C. Each possibility is a separate embodiment. According to some embodiments, the resistive conductor core is stable at a temperature of at least about 300° C. According to some embodiments, the resistive conductor core is stable at a temperature of at least about 350° C. In some embodiments, upon heating the resistive conductor core at a high temperature, no change in electric (linear) resistance is observed.

In some embodiments, upon heating the resistive conductor core at a high temperature (e.g., above 250° C., above 300 ° C., or above 350° C.), no change in electric (linear) resistance is observed.

In some embodiments, upon heating the resistive conductor core to a high temperature (e.g., above 250° C., above 300° C., or above 350° C.), no deformation of the fibers is observed.

According to some embodiments, the resistive conductor core is stable at a temperature of about 200-370 ° C., for example, about 210-370° C., about 220-370° C., about 220-360° C., about 230-360 ° C., about 230-350° C., about 230-340° C., about 230-340° C., about 240-340° C., about 240-330 ° C., about 250-330 ° C., about 250-340 ° C., about 250-350° C., about 230-320° C., about 200-350° C., about 270-350° C., about 270-330° C., about 210-300° C., or about 270-360° C. Each possibility is a separate embodiment.

According to some embodiments, the resistive conductor core is characterized by an electric resistance (i.e., linear resistance) of about 10-500 kΩ/m, for example, about 10-400 kΩ/m, about 10-300 kΩ/m, about 10-200 kΩ/m, or about 10-100 kΩ/m. Each possibility is a separate embodiment. According to some embodiments, the resistive conductor core is characterized by an electric resistance (i.e., linear resistance) of about 10-200 kΩ/m, for example, 10-190 kΩ/m, 10-180 kΩ/m, 10-160 kΩ/m, 10-150 kΩ/m, 10-130 kΩ/m, 10-120 kΩ/m, 10-100 kΩ/m, 10-80 kΩ/m, 10-50 kΩ/m, 15-50 kΩ/m, or 20-50 kΩ/m. Each possibility is a separate embodiment. According to some embodiments, the resistive conductor core is characterized by an electric resistance, i.e., linear resistance, of about 10-100 kΩ/m, for example, about 10-90 kΩ/m, about 10-85 kΩ/m, about 10-75 kΩ/m, about 15-75 kΩ/m, about 15-70 kΩ/m, about 15-65 kΩ/m, about 15-60 kΩ/m, about 15-55 kΩ/m, or about 20-45 kΩ/m. Each possibility is a separate embodiment. According to some embodiments, the resistive conductor core is characterized by an electric resistance, i.e., linear resistance, of about 1-100 kΩ/m, for example, about 2-90 kΩ/m, about 5-80 kΩ/m, about 10-60 kΩ/m, about 10-50 kΩ/m, about 11-45 kΩ/m, or about 15-50 kΩ/m. Each possibility is a separate embodiment.

According to some embodiments, the diameter of the resistive conductor core is about 0.5-5 mm, for example, about 0.5-2 mm, about 1-1.5 mm, about 0.5-1.5 mm, about 0.5-1.0 mm, about 2-5 mm, about 1.5-4.5 mm, about 1.5-3 mm, or about 2.5-5 mm. Each possibility is a separate embodiment.

According to some embodiments, the resistive conductor core may withstand at least 20 arcs at a potential of 15 kV in air conditions, with less than 20% reduction of linear resistance. For example, in some embodiments, the core exhibits, less than 18%, less than 15%, less than 10%, or less than 5% reduction of linear resistance, upon at least 20 arcs at a voltage potential of 15kV, in air conditions. Each possibility is a separate embodiment. For example, in some embodiments, the resistive conductor core may withstand at least 20 arcs, at least 25 arcs, at least 30 arcs, or at least 40 arcs, when a potential of 15 kV is applied to it, in air conditions, with less than 20% reduction of (linear) resistance. Each possibility is a separate embodiment.

There is provided, in accordance with some embodiments, a scanning electron microscope (SEM) including a high voltage (HV) resistive conductor cable for operation under vacuum conditions, the cable includes a resistive conductor core coated with an insulating material configured to prevent leakage of contaminants through the insulating material when operating under vacuum conditions, wherein said resistive conductor core includes glassy fibers and conductive carbon, wherein the conductive carbon is about 2-25% (w/w) of the resistive conductor core, such that the resistive conductor core is characterized by having an electric resistance of about 1-500 kΩ/m and by being configured to withstand a temperature of at least about 250° C.

According to some embodiments, the high voltage (HV) resistive conductor cable is located in a vacuum chamber of the SEM.

According to some embodiments, the SEM includes a wafer-holding assembly to which the herein disclosed resistive conductor cable is electrically connected.

There is provided, in accordance with some embodiments, a method of using the HV resistive conductor cable disclosed herein, the method including electrically connecting a high-voltage power supply to a wafer-holding assembly by using the high voltage (HV) resistive conductor cable.

According to some embodiments, the resistive conductor cable is used to electrically connect a high-voltage power supply to a wafer-holding assembly. In some embodiments, the resistive conductor cable is used for sample biasing. The applied voltage enables optimized imaging. In some embodiments, the applied voltage facilitates control over beam penetration and a resulting image resolution.

In some other embodiments, the resistive conductor cable is used to electrically connect a high-voltage power supply to an electrostatic lens.

In some other embodiments, the resistive conductor cable is used to electrically connect a high-voltage power supply to an electron gun.

There is provided, in accordance with some embodiments, a method of producing a high voltage (HV) resistive conductor cable for operation under vacuum conditions, the method includes:
providing a resistive conductor core including glassy fibers and conductive carbon, wherein the conductive carbon is about 2-25% (w/w) of the resistive conductor core and wherein the resistive conductive core is characterized by having a resistance of about 1-500 kΩ/m and by being configured to withstand a temperature of at least about 250° C.;
superimposing an insulating material around the resistive conductor core, wherein the insulating material is configured to prevent leakage of contaminants therethrough when operating under vacuum conditions; and
heating the insulating material at a temperature of at least about 250° C., to produce the high voltage (HV) resistive conductor cable suitable for use under vacuum conditions.

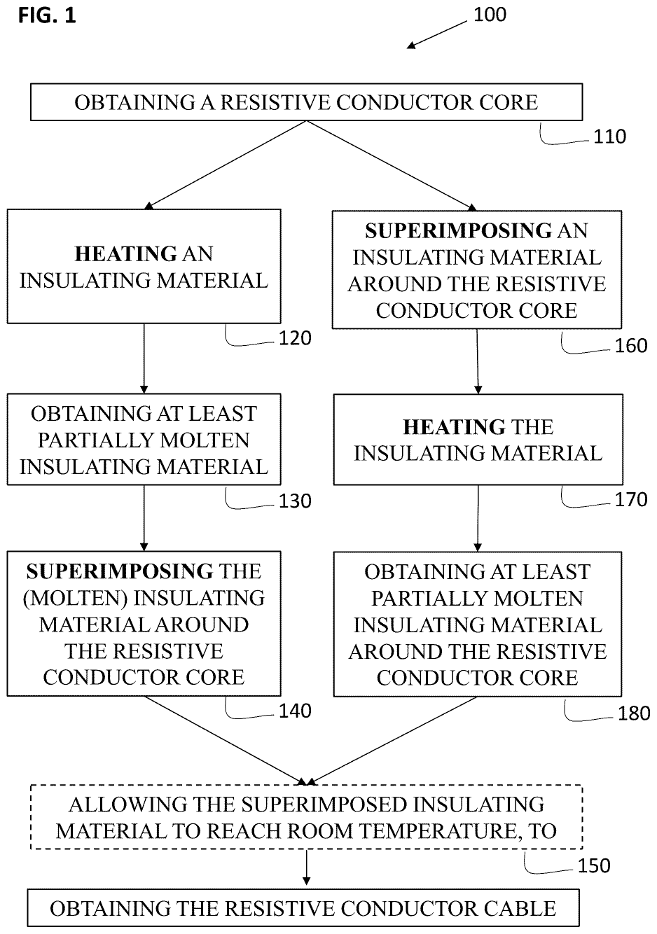

Reference is now made to FIG. 1 which schematically illustrates a flowchart of a method for producing the resistive conductor cable disclosed herein. As shown in FIG. 1, production method 100 includes step 110 obtaining a resistive conductor core. According to some embodiments, the resistive conductor core may include, for example, glass fibers coated with conductive carbon.

According to some embodiments, in step 120, an insulating material is heated. In some exemplary embodiments, the insulating material may be polytetrafluoroethylene (i.e., PTFE, Teflon®) or fluorinated ethylene propylene (FEP). The heating temperature may be, for example, a temperature that is above 250° C., above 300° C., or above 350° C. Each possibility is a separate embodiment. In step 130, at least partially molten insulating material is obtained from the heating step (120), according to some embodiments. In some embodiments, the molten insulating material may optionally be dispensed in a container/bath. In step 140, the (at least partially) molten insulating material is superimposed around the resistive conductor core, thereby inevitably heating the resistive conductor core to a temperature above 200° C. In some exemplifying embodiments, the superimposed (at least partially) molten insulation material is further extruded around the resistive conductor core. The extrusion produces a thin layer of the at least partially molten insulating material around the resistive conductor core. In step 150, the superimposed at least partially molten insulating material is allowed to reach room temperature, to produce the resistive conductor cable.

According to some other embodiments, in step 160, the insulating material is initially superimposed around the resistive conductor core. In some exemplifying embodiments, the insulating material may be in a form of a thin tape. The insulating material tape may be wrapped around the resistive conductor core. In step 170, the insulating material superimposed around the resistive conductor core is heated. The heating temperature may be, for example, a temperature that is above 250° C., above 300° C., or above 350° C. Each possibility is a separate embodiment. In step 180, according to some embodiments, an at least partially molten insulating material is obtained around the resistive conductor core. An adhered insulating material layer may thus be obtained around the resistive conductor core, in some embodiments. In some embodiments, the at least partially molten insulating material around the resistive conductor core is allowed to cool down, for example, to room temperature.

In some embodiments, the set of steps 120 to 140 may be combined with the set of steps 160 to 180, to produce the herein disclosed resistive conductor cable.

According to some embodiments, the heating of the insulating material can be performed before the superimposing of the (at least partially molten) insulating material around the resistive conductor core. According to some embodiments, the superimposing of the insulating material around the resistive conductor core can be performed before the heating of the insulating material in order to associate the insulating material with the core.

According to some embodiments, the heating of the insulating material allows the melting of at least a portion or all of the material. According to some embodiments, the heating of the insulating material produces at least partially molten insulating material. In some embodiments, the at least partially molten insulating material may be applied to the resistive conductor core, to produce the resistive conductor cable disclosed herein.

According to some embodiments, the heating of the insulating material is at a temperature of at least about 250° C., for example, at least about 260° C., at least about 270° C., at least about 280° C., at least about 290° C., at least about 300° C., at least about 310° C., at least about 320° C., at least about 330 ° C., at least about 340° C., at least about 350° C., at least about 360 ° C., or at least about 370° C. Each possibility is a separate embodiment. According to some embodiments, the heating of the insulating temperature is at a temperature of at least about 300° C. According to some embodiments, the heating of the insulating temperature is at a temperature of at least about 350° C. In step 150, the superimposed at least partially molten insulating material around the resistive conductor core is allowed to reach room temperature, to produce the resistive conductor cable.

According to some embodiments, the insulating material is heated while physically associated with the resistive conductor core. Thus, in some embodiments, the heat is transferred to the resistive conductor core.

According to some embodiments, the heating of the insulating temperature is at a temperature of about 200-370° C., for example, about 210-370° C., about 220-370° C., about 220-360 ° C., about 230-360 ° C., about 230-350° C., about 230-340° C., about 230-340° C., about 240-340 °0 C., about 240-330° C., about 250-330° C., about 250-340° C., about 250-350° C., about 230-320 °0 C., about 200-350° C., about 270-350° C., about 270-330° C., about 210-300° C., or about 270-360° C. Each possibility is a separate embodiment.

According to some embodiments, the method of producing the HV resistive conductor cable may further include extrusion of the (at least partially molten) insulating material around the resistive conductor core. In some embodiments, the method includes applying a molten insulating material onto the resistive conductor core using an extrusion process. In some embodiments, a bath containing the molten insulating material is held at a temperature of at least about 250° C., at least about 300° C., or at least about 350° C. Each possibility is a separate embodiment. In some embodiments, the resistive conductor core is passed through the bath containing the molten insulating material, to obtain a resistive conductor core superimposed with a molten insulating material. In some embodiments, the resistive conductor core is passed through an extruder while superimposed with the molten insulating material, to produce the resistive conductor core coated with the insulating material. In some embodiments, the extruded resistive conductor core while superimposed with the molten insulating material is allowed to cool down, to provide with the resistive conductor core coated with the insulating material.

In some embodiments, the insulating material is heated, melted, deposited around the resistive conductor core, and then forced through an extrusion die while deposited/wrapped around the resistive conductor core. In some embodiments, the method includes forming a thin film of molten insulating material that is pressed onto the core using rollers.

In some embodiments, the method includes applying pressure on the resistive conductor core and the molten insulating material, during the extrusion.

According to some other embodiments, the superimposing of the insulating material may be done by wrapping a tape or a sleeve of the insulating material around the resistive conductor core. In some embodiments, the tape/sleeve is heated at a temperature of at least about 250° C., at least about 300 °0 C., or at least about 350° C. Each possibility is a separate embodiment. In some embodiments, heating the wrapped insulating material results in heating of the resistive conductor core (heat-shrinking).

According to some other embodiments, the method further includes wrapping a thin tape of the insulating material around the resistive conductor core. In some embodiments, the coated/wrapped insulating material tape is heated, to produce the resistive conductor core coated with the insulating material. In some embodiments, the resistive conductor core wrapped by a molten insulating material tape. In some embodiments, the wrapped resistive conductor core is allowed to cool down, to provide with the resistive conductor core coated with the insulating material.

According to some embodiments, the wrapping of the insulating material and the extrusion of the insulating material, around the resistive conductor core, may be combined to produce the resistive conductor core coated with the insulating material, i.e., the resistive conductor cable disclosed herein.

According to some embodiments, the method further includes allowing the produced resistive conductor core coated with the insulating material to reach room temperature.

Unless defined otherwise, all technical and scientific terms used herein have the same meaning as is commonly understood by one of skill in the art to which this subject matter pertains. The following definitions are provided for clarity.

As used herein, according to some embodiments, the term “glassy fibers” refers to fibers made from glass or glass-like materials, characterized by their amorphous (non-crystalline) structure. Examples of glassy fibers may include, but not limited to, according to some embodiments, fiberglass, basalt fibers, or borosilicate glass fibers.

As used herein, according to some embodiments, the term “resistive conductor” refers to a material that allows electric current to flow through it but also exhibits resistance, causing energy to be dissipated (such as in the form of heat). In some exemplifying embodiments, a resistive conductor may be a composite material including a conductive material and a non-conductive material, such as glassy fibers and conductive carbon.

As used herein, according to some embodiments, the term “core” or “resistive conductor core” refers to a part of a cable that is a central component serving as the primary medium for conducting and resisting electricity. In some embodiments, the core may include a conductive material. In some embodiments, the core may include a non-conductive material. In some embodiments, the core may include a (non-conductive) material in a form of a single solid strand and/or multiple smaller strands (e.g., glassy fibers). In some embodiments, the core may include a (conductive) material impregnated/coating the strand(s) (e.g., conductive carbon).

As used herein, according to some embodiments, the term “insulating material” refers to a substance that resists a flow of electric current, thus preventing the transfer of electricity or heat. According to some embodiments, the term “insulating material” refers to a material that may coat a resistive conductor core and prevent contaminants originating from the core from reaching the surroundings of the insulating material. Examples of insulating material may include, but are not limited to, Teflon®, FEP, or Kapton®, in some embodiments.

As used herein, according to some embodiments, the term “contaminants” refers to unwanted substances or impurities that may be present in a material, environment, or system, potentially causing harm, reducing quality, or interfering with functionality. In some embodiments, the contaminants may be a chemical element, such as carbon element or metal element. In some embodiments, the contaminants may originate from the resistive conductor core. In some embodiments, the contaminants may originate from the environment. In some embodiments, the contaminants may be transferred from one component to another component in a system (i.e., cross-contamination). In some embodiments, examples of components that may be contaminated may include, but not limited to, HV resistive conductor cable, HV resistive conductor core, or wafer-holding assembly.

As used herein, according to some embodiments, the term “withstand a temperature” refers to the ability of a material to endure exposure to a specific temperature range without degradation, deformation, loss of functionality, or failure. In some embodiments, the ability to withstand a temperature, such as a high temperature, refers to the ability of a material to endure exposure to a specific temperature range with less than 5%, less than 4%, less than 3%, less than 2%, less than 1%, or less than 0.5% of degradation, deformation, loss of functionality, or failure. Each possibility is a separate embodiment.

The term “a” or “an” as used herein includes the singular and the plural, unless specifically stated otherwise. Therefore, the terms “a,” “an,” or “at least one” can be used interchangeably in this application.

As used herein, the verb “comprise” as is used in this description and in the claims and its conjugations are used in its non-limiting sense to mean that items following the word are included, but items not specifically mentioned are not excluded.

As used herein, the term “about” when used in connection with a numerical value includes ±10% from the indicated value. In addition, all ranges directed to the same component or property herein are inclusive of the endpoints, are independently combinable, and include all intermediate points and ranges. It is understood that where a parameter range is provided, all integers within that range, and tenths thereof, are also provided by the invention.

In the herein provided description, various aspects of the disclosure were described. For the purpose of explanation, specific configurations and details are set forth in order to provide a thorough understanding of the different aspects of the disclosure. However, it will also be apparent to one skilled in the art that the disclosure may be practiced without specific details being presented herein. Furthermore, well-known features may be omitted or simplified in order not to obscure the disclosure.

The following examples are presented in order to more fully illustrate some embodiments of the invention. They should, in no way be construed, however, as limiting the broad scope of the invention. One skilled in the art can readily devise many variations and modifications of the principles disclosed herein without departing from the scope of the invention.

### EXAMPLES

Example 1: Stability of the herein disclosed resistive conductor core at a high temperature

The herein disclosed resistive conductor core was heated on a hot plate at a temperature of 350° C., for 30 minutes. As a result, no change in resistance and no deformation of the fibers was observed.

Example 2: Arcing the herein disclosed resistive conductor core in air

Upon performing ~20 arcs on the resistive conductor core at 15 kV, in air, no change in resistance was observed.

Example 3: Forced discharge measurements on an insulated, resistive conductor core disclosed herein

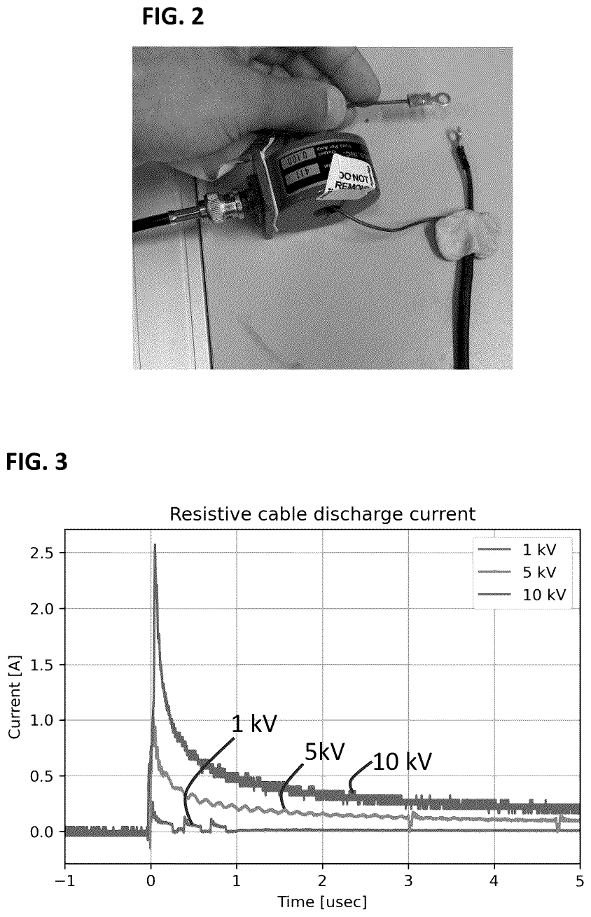

Forced discharge measurements were conducted on a 5 m insulated resistive conductor core disclosed herein, having a resistance of between 1-100 kΩ/m. The resistive conductor core was insulated using 20 kV shrink for insulation and the resistance was 173 kΩ. FIG. 2 shows an image of the insulated resistive conductor core used for forced discharge measurements.

Voltages of 1 kV, 5 kV, and 10 kV were applied to the insulated resistive conductor core, and the current was measured vs. time (FIG. 3). Advantageously, the resistive conductor core demonstrated a behavior that is comparable to a cable conductor connected to a resistor.

Example 4: Comparison of forced discharge measurements of a resistive conductor core disclosed herein, vs. a standard coax cable connected to a resistor

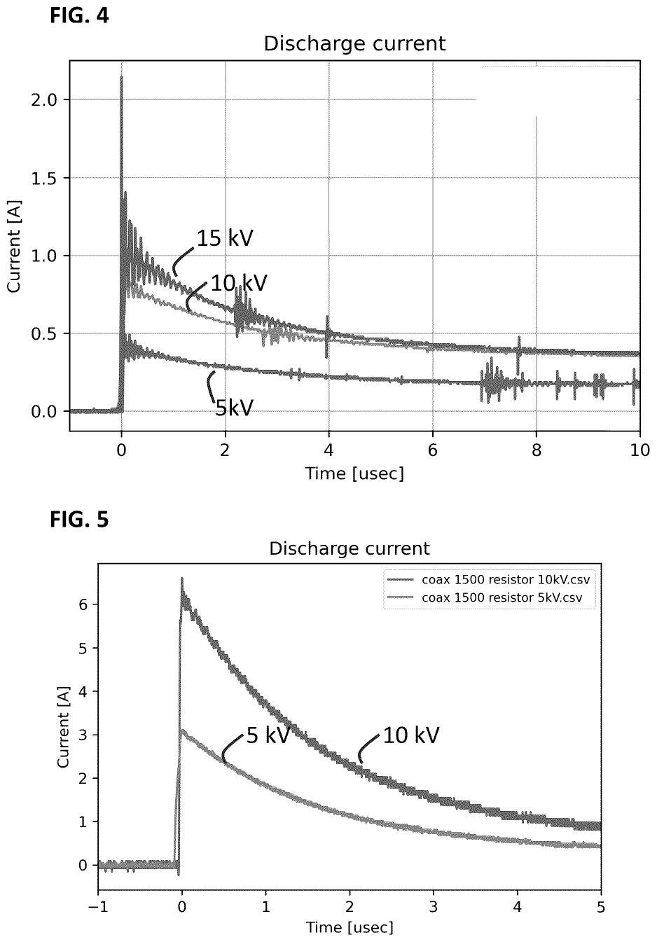

The resistive conductor core having a resistance between 1-100 kΩ/m. Voltages of 5 kV, 10 kV, and 15 kV were applied to the resistive conductor core for forced discharge measurements. The arc was forced by touching the core with a shield (FIG. 2). The current was measured as the core was discharged (FIG. 4). The resistive conductor core's obtained resistance was ~12 kΩ DC. FIG. 4 shows the measured current (shown in the Y axes) vs. time (shown in the X axes), to evaluate peak discharge current and its decay over time.

Similar measurements were performed on a 6 m standard coax cable connected to a resistor of 1.5 kΩ, by applying 5 kV and 10 kV voltages (FIG. 5).

Advantageously, the resistive conductor core demonstrated behavior that is comparable to a cable conductor connected to a resistor having a resistance within a similar range value.

It can be noted in FIG. 4 and FIG. 5 that the decay-time constant is similar. The time frame of the decay during arcing is in the range of micro-seconds (0-8 μsec).

Moreover, advantageously, after ~20 arcs at 15 kV, the resistance value stayed within the measurement error.

A current probe of 0.1 V equivalent to 1 A current on sample (0.1V->1A), was used for the measurement. The amplitude of the arc appeared to be similar between the two systems. The resistance of the resistive conductor core were measured before and after the discharge test to ensure stability.

Example 5: Forced discharge comparable measurements of the herein disclosed resistive conductor core vs. a simulated model of a standard coax cable connected to a resistor

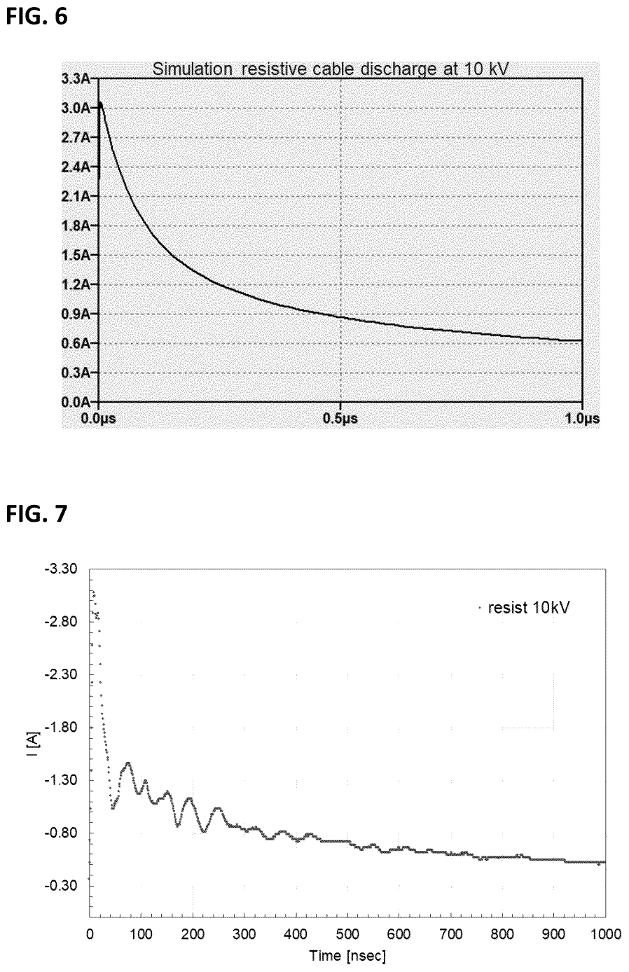

A model of a standard cable connected to a resistor was built. The model, which was made to meet the resistance value of the core, was utilized to compare its simulated current discharge graph (FIG. 6) to the experimental results graph of the herein disclosed resistive conductor core having a resistance of between 1-100 kΩ/m (FIG. 7). The applied voltage was 10 kV in both model and experiment and the current (Y axes) was measured vs. time (X axes) during the discharge. Advantageously, as it can be seen from the two graphs (FIG. 6 and FIG. 7), there is an adequate match between the measured data and the model. Thus, the resistive conductor core behaves like a standard coax cable connected to a resistor having the same expected resistance value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain embodiments of the invention have been illustrated and described, it will be clear that the invention is not limited to the embodiments described herein. Numerous modifications, changes, variations, substitutions and equivalents will be apparent to those skilled in the art without departing from the spirit and scope of the present invention as described by the claims, which follow.

1. A high voltage (HV) resistive conductor cable for operation under vacuum conditions, the cable comprising a resistive conductor core coated with an insulating material configured to prevent leakage of contaminants when operating under vacuum conditions, wherein said resistive conductor core comprises glassy fibers and conductive carbon, wherein the conductive carbon is about 2-25% (w/w) of the resistive conductor core, such that the resistive conductor core is characterized by having an electric resistance of about 1-500 kΩ/m and by being configured to withstand a temperature of at least about 250 ° C.

2. The HV resistive conductor cable of claim 1, characterized by a bending diameter of about 5-20 times the diameter size thereof, when the HV resistive conductor cable is in a recurrent motion.

3. The HV resistive conductor cable of claim 1, characterized by a bending diameter of about 5-10 times the diameter size thereof, when the HV resistive conductor cable is in a recurrent motion.

4. The HV resistive conductor cable of claim 1, wherein the conductive carbon is selected from a group consisting of graphitic carbon, amorphous carbon, pyrolyzed carbon, doped carbon, carbon aerogel or foam, carbon quantum dots or nanodots, carbon-organic composite, onion-like carbon, mesoporous carbon, and any combination thereof.

5. The HV resistive conductor cable of claim 4, wherein the graphitic carbon is selected from a group consisting of graphite, graphene, expanded graphite, pyrolytic graphite, graphene oxide (reduced), graphite oxide nanoparticles (reduced), graphene oxide nanoparticles (reduced), graphene quantum dots, graphene nanoparticles, graphene nanoplatelets, graphene oxide nanosheets, graphene-functionalized nanoparticles, carbon nanotube-graphene composites, graphite nanoparticles, graphite nanosheet, graphite nanofibers, graphitic carbon nitride (g-C3N4), few-layer graphene, highly oriented pyrolytic graphite (HOPG), multilayer graphene, carbon nanotubes (CNTs), carbon nanofibers (CNFs), fullerenes (e.g., C60), carbon nanocages, and any combination thereof.

6. The HV resistive conductor cable of claim 5, wherein the graphitic carbon is selected from a group consisting of graphite, graphene, expanded graphite, pyrolytic graphite, graphene oxide (reduced), graphene oxide nanoparticles (reduced), graphite oxide nanoparticles (reduced), graphene quantum dots, graphene nanoparticles, graphene nanoplatelets, graphene oxide nanosheets, graphene-functionalized nanoparticles, carbon nanotube-graphene composites, graphite nanoparticles, graphite nanosheet, graphite nanofibers, carbon nanotubes (CNTs), and any combination thereof.

7. The HV resistive conductor cable of claim 1, wherein the glassy fibers are selected from a group consisting of fiberglass, silicon rubber fibers, basalt fibers, boron fibers, borosilicate fibers, any derivative thereof, and any combination thereof.

8. The HV resistive conductor cable of claim 7, wherein the resistive conductor core comprises glassy fibers selected from: fiberglass, basalt fibers, and borosilicate fibers, and graphitic carbon selected from: graphite, graphene, graphite oxide nanoparticles (reduced), graphene nanoparticles, graphene nanoplatelets, graphene oxide nanosheets, graphene-functionalized nanoparticles, graphite nanoparticles, graphite nanosheet, graphite nanofibers, and any combination thereof.

9. The HV resistive conductor cable of claim 1, wherein the glassy fibers are coated with the conductive carbon.

10. The HV resistive conductor cable of claim 1, wherein the insulating material comprises polytetrafluoroethylene (PTFE), polyimide, silicon rubber, polyethylene (PE), polyvinyl chloride (PVC), fluorinated ethylene propylene (FEP), any derivative thereof, any co-polymer thereof, or any combination thereof.

11. The HV resistive conductor cable of claim 10, wherein the insulating material is PTFE.

12. The HV resistive conductor cable of claim 1, wherein the vacuum conditions are characterized by a pressure range of between 10⁻⁵ to 1·10⁻¹² Torr.

13. The HV resistive conductor cable of claim 1, wherein the cable is configured to operate at a high voltage (HV) of between about 10 kV to 500 kV.

14. The HV resistive conductor cable of claim 13, wherein the high voltage (HV) is in a range of between about 10 kV to 300 kV.

15. The HV resistive conductor cable of claim 1, wherein the resistive conductor core is stable at a temperature of at least about 300° C.

16. The HV resistive conductor cable of claim 1, wherein the resistive conductor core is characterized by an electric resistance of about 10-100 kΩ/m.

17-20. (canceled)
